(19) United States
(12) Patent Application Publication
(10) Pub. No.: US 2025/0377388 A1
(43) Pub. Date: Dec. 11, 2025

(54) POSITIONING AID FOR A CORELESS CURRENT SENSOR

(71) Applicant: BOURNS, INC., Riverside, CA (US)

(72) Inventors: Gerhard Wessels, Aschheim (DE); Maxim D. Tarakhovsky, Lake Orion, MI (US)

(21) Appl. No.: 19/228,389

(22) Filed: Jun. 4, 2025

(30) Foreign Application Priority Data
Jun. 5, 2024 (DE) 10 2024 115 678.3

(51) Int. Cl. G01R 19/00; G01D 11/18; G01D 11/24

(52) U.S. Cl. CPC G01R 19/0092; G01D 11/18; G01D 11/245

(57) ABSTRACT

Examples described herein relate to a device for positioning a coreless sensor relative to an electrical conductor carrying an electric current in a current flow direction, comprising a housing delimiting an interior space for receiving the coreless sensor, a through-opening passing through the housing in the current flow direction, into which the electrical conductor is form-fit insertable transverse to the current flow direction, and a holding device, arranged in the interior space at a predetermined distance transverse to the current flow direction, for holding the coreless sensor in a predetermined position relative to the through-opening.

### RELATED APPLICATIONS

This application claims the benefit of German Patent Application No. DE102024115678.3, filed Jun. 5, 2024, the entire content of which is hereby incorporated by reference.

### FIELD

Examples described herein relate to a positioning aid for a coreless current sensor.

### SUMMARY

The relative position between coreless sensors and the electrical conductor whose current they are to detect influences their function. Conventionally, coreless sensors are therefore calibrated, as exemplified in DE 10 2022 212 545 A1.

The object of the invention is to at least simplify or even eliminate the calibration of coreless sensors.

The object is achieved by the features of the independent claims. Preferred embodiments are the subject of the dependent claims.

According to one aspect of the invention, the device for positioning a coreless sensor relative to an electrical conductor carrying an electrical current in a current flow direction comprises:
a housing delimiting an interior space for receiving the coreless sensor;
a through-opening passing through the housing in the current flow direction, in which the electrical conductor can be positively fitted transversely to the current flow direction, and
a device arranged within the interior space at a predetermined distance transversely to the current flow direction for holding the coreless sensor in a predetermined position relative to the through-opening.

The specified device for positioning a coreless sensor enables precise and accurate alignment of the sensor relative to the electrical conductor. The housing with the through-opening, through which the electrical conductor is inserted transversely to the current flow direction, ensures a form-fit and thus stable placement of the conductor. This construction ensures that the conductor is always in a defined position relative to the through-opening and thus to the sensor.

The sensor itself is fixed within the housing at a predetermined distance transversely to the current flow direction by means of a holding device. This arrangement ensures that the sensor is always positioned in the relative position to the electrical conductor in which the magnetic field induced by the electrical current is optimal for current measurement. Due to the exact and reproducible positioning of the sensor in relation to the conductor, in which the physical conditions for measurements always remain the same, the necessity for the aforementioned calibration is significantly reduced, if not eliminated.

The precise positioning enables consistent measurement results and minimizes potential sources of error that can occur with free positioning of the electrical conductor relative to the sensor. Therefore, the aforementioned calibration of the sensor, which would normally be necessary to correct deviations due to positioning errors, can be simplified or completely avoided. This increase in efficiency leads not only to more reliable measurement values but also to simplified handling and maintenance of the entire measuring device.

In one embodiment, the specified device comprises latching hooks, which are configured to hold the electrical conductor in a direction transverse to the current flow direction.

The integration of latching hooks into the specified device offers further advantages by securely and stably holding the electrical conductor in the direction transverse to the current flow direction. These latching hooks engage the conductor in a form-fitting manner and prevent it from shifting or vibrating during the measurement. As a result, a constant positioning of the conductor relative to the sensor is ensured, which further increases the accuracy of the measurements.

A significant advantage of this design is the further reduction of the risk of displacement of the electrical conductor relative to the sensor and thus the further reduction of the need for calibration. Since the latching hooks precisely fix the conductor, the spatial relationship between the sensor and the conductor remains constant, even when the device is used frequently or in different environments. This consistency in positioning eliminates many of the variable factors that would normally require calibration of the sensor.

Furthermore, the latching hooks facilitate the installation and setup of the device. Technicians can quickly and easily insert the conductor into the device, with the latching hooks immediately providing a secure hold. This speeds up the entire preparation process for measurements and minimizes the time required for the adjustment and maintenance of the device.

In summary, the latching hooks not only improve measurement accuracy through more stable positioning of the conductor but also simplify the handling of the device and reduce the need for recurring calibration. This leads to more efficient workflows and more reliable results when using the sensor in practical applications.

In an additional embodiment, the specified device comprises support legs for supporting the electrical conductor, such that the electrical conductor is positionable in the direction transverse to the current flow direction between the latching hooks and the support legs.

The addition of support legs for supporting the electrical conductor in the specified device enhances the functionality and stability of the system and additionally contributes to the reduction of the need for calibration. These support legs ensure that the conductor is firmly and securely positioned between them and the latching hooks. This increases the mechanical stability of the conductor by preventing potential movements and vibrations during the measurement.

The fixed position of the conductor provided by the support legs helps ensure that the distance and alignment to the sensor can be maintained over a longer period of time. Such a configuration minimizes influencing factors that could lead to measurement deviations, such as accidental shifting of the conductor or changes in the physical environment. This directly contributes to higher accuracy and reliability of the measurement data.

Another advantage of the support legs is the simplification of the setup process. Technicians can insert the conductor into the device quickly and without great effort, with the combination of latching hooks and support legs enabling immediate and effective fixation. This saves time and reduces the complexity of preparing measurements.

Due to the robust construction achieved by the addition of support legs, the overall service life of the device is improved. Since less physical stress is placed on the individual components, fewer maintenance and repair operations are required.

In another embodiment of the specified device, the housing comprises a first housing part and a second housing part, with which the first housing part can be closed.

The design of the device with a first and a second housing part, which can be closed together, offers several advantages, particularly concerning handling, safety, and calibration requirements.

Firstly, the two-part housing enables easy access to the interior of the device. This is especially useful when inserting the sensor and the electrical conductor, as well as during maintenance work. Technicians can open the housing, position or replace the components without difficulty, and then securely close the housing again. This accessibility significantly simplifies the setup process and reduces the time required to prepare and carry out the measurements.

Secondly, the closable design ensures high stability and security of the internal components. When the housing is closed, the sensor and the electrical conductor are firmly and securely positioned, which minimizes the likelihood of movement or vibrations that could impair measurement accuracy. This consistency is crucial to reduce the need for frequent calibrations, as the measurement conditions remain stable.

Thirdly, the closable housing provides additional protection against external influences such as dust, moisture, and mechanical damage. This preserves the integrity of the sensors and other sensitive components and ensures that their performance and reliability are maintained over longer periods. This contributes to calibration being needed less frequently, as the environmental conditions have less influence on measurement accuracy.

Overall, the design with a first and second closable housing part results in the device being easier to handle, safer to use, and more robust against environmental influences. This leads to a reduction in the need for calibrations, which lowers operating costs and improves the efficiency and reliability of the measurement processes.

In a specific embodiment of the specified device, the through-opening is formed as a recess that is open on one side transverse to the current flow direction in at least one of the housing parts, which can be closed by placing the corresponding other housing part.

The concept of the through-opening as a one-sided open recess in at least one of the housing parts, which is closable by placing the other housing part, offers an innovative solution that significantly improves both the functionality and precision of the device.

A key advantage of this design is the simplification of the installation of the electrical conductor. Since the recess is open on one side, the conductor can be easily and quickly inserted from one side without having to be threaded through the housing. This reduces the time and effort required to insert and remove the conductor and facilitates the entire assembly process.

Once the second housing part is placed, the recess is closed, thereby holding the conductor securely and firmly in position. This type of fixation ensures very accurate positioning of the conductor relative to the sensor, which is crucial for measurement accuracy. By precisely defining and stabilizing the position of the conductor, measurement deviations caused by vibrations or displacements of the conductor can be minimized.

This precise and secure anchoring of the conductor in the through-opening directly contributes to the reduction of the need for calibration. Since the conductor is held firmly in position, the conditions for the measurements remain constant, which increases accuracy and reduces the frequency of required calibrations. This is especially important in applications where high precision and reliability of the measurement results are required.

Furthermore, the design with the one-sided open recess that is closable by the other housing part provides additional protection for the conductor. It protects it from external influences such as dust and moisture, which extends the service life of the components and reduces maintenance costs.

In a specific embodiment of the specified device, transverse securing elements are formed on the recess.

The transverse securing elements may be the above-mentioned latching hooks, which are formed directly on the recess in one of the housing parts and further optimize the functionality of the device. The placement of the latching hooks on the recess, where the electrical conductor is inserted, offers a number of advantages that positively impact the precision and handling of the device.

First of all, this arrangement ensures a very direct and robust fixation of the conductor exactly at the point where the measurement takes place. The latching hooks formed on the recess securely clamp the conductor and prevent it from shifting during measurement. This firm and immovable positioning is essential for the accuracy of the measurement results, as any movement of the conductor could potentially distort the measurement data.

This stable fixation by the latching hooks reduces the need for regular calibrations. Since the conductor is always held in exactly the same position, the conditions for the measurements remain constant. This leads to higher reliability of the measured values and reduces the likelihood that deviations must be corrected due to positional changes of the conductor.

Another advantage of this configuration is the simplification of the installation process. The latching hooks, which are positioned directly on the recess, allow for quick and easy insertion of the conductor into the device. Technicians can simply place the conductor into the recess, and the latching hooks automatically ensure a secure locking. This speeds up the entire setup process and minimizes the time required to prepare the measurements.

Finally, the integration of the latching hooks at the recess also provides additional mechanical protection for the conductor. By holding the conductor firmly in place, it is protected from external influences that could otherwise cause damage or wear. This contributes to the durability of the device and the consistency of the measurements over extended periods.

In another embodiment, the specified device comprises latching elements, which are configured to latch the two housing parts together in an assembled state to form the housing.

The inclusion of latching elements configured to latch the two housing parts together in an assembled state brings essential advantages for the stability and functionality of the device, which in turn improves measurement accuracy and can reduce the need for calibration.

Firstly, these latching elements ensure a firm and permanent connection of the two housing parts. When the housing parts are securely latched together, the entire structure of the device becomes more stable. This is particularly important, as any play or movement between the housing parts could lead to variations in the position of the sensor relative to the conductor, which would impair measurement accuracy. A solid and unchanging structure ensures that the sensor and the electrical conductor remain in a constant, predetermined relation to each other, which guarantees consistently high measurement quality.

Secondly, the latching elements facilitate the assembly and disassembly of the device. They allow users to quickly assemble or disassemble the housing parts without additional tools. This greatly simplifies the process of inserting or replacing components and saves time in preparing the measurements. The ease of use provided by the latching elements makes the device more user-friendly and minimizes human errors during assembly.

Thirdly, the latching elements help protect the device against external influences such as vibrations, shocks, or environmental effects that could otherwise affect the components. This protective function is essential to ensure the longevity and reliability of the measuring device and to reduce the need for regular maintenance and calibration.

Finally, the latching elements allow calibration settings that have once been established to be preserved, even when the device is frequently transported or reassembled. This stabilizes the measurement conditions over longer periods and across different usage locations, and often makes repeated calibrations unnecessary.

In a further embodiment, the specified device comprises a guide groove extending transverse to the current flow direction on one of the housing parts, into which a correspondingly formed guide protrusion on the other housing part can be inserted for assembling the two housing parts into the housing guided transversely to the current flow direction.

The concept of a guide groove in one of the housing parts and a corresponding guide protrusion on the other housing part provides an intelligent solution for precise and reproducible alignment of the housing parts with respect to each other. This design offers several advantages that specifically improve the assembly accuracy, stability, and maintenance-friendliness of the device and directly contribute to minimizing the need for calibration.

Firstly, the guide groove guide protrusion construction ensures exact and simple joining of the housing parts. This precise guidance facilitates the assembly of the components by ensuring that the housing parts are correctly aligned each time, leaving no room for human error. Such accurate positioning is essential as it guarantees consistency in the placement of the sensor and conductor within the housing, which directly affects measurement accuracy.

Secondly, the precise guidance of the housing parts by groove and protrusion reduces mechanical stress and wear that could occur with frequent assembly and disassembly. This increases the service life of the device and minimizes the need for repairs or replacement of components. This, in turn, contributes to lower maintenance costs and improved overall system reliability.

Thirdly, the stable and precise connection of the housing parts reduces vibrations and movements during operation. This stability is particularly important in environments where external influences such as shocks or impacts could distort measurement results. The guide groove and guide protrusion ensure that the sensor is held in a firmly defined position relative to the conductor, significantly reducing the need for calibration after each assembly of the device.

Finally, the guide groove and protrusion also offer added security during regular transport of the device, ensuring that the alignment of the components remains constant. This is particularly beneficial in scenarios where the device is used at different locations and must be repeatedly assembled and disassembled.

In a further embodiment of the specified device, an edge of the through-opening is formed tapered in a direction transverse to the current flow direction.

The idea of forming an edge of the through-opening to be tapered improves the precision and stability of the electrical conductor within the device, especially when the housing material exhibits a certain elasticity, as is the case with plastic. This design and choice of material offer several advantages.

Firstly, the tapered edge of the through-opening increases the contact area between the housing and the electrical conductor. When the housing material, such as plastic, is elastic, it can easily adapt to the shape of the conductor and gently compress around it. This adaptability results in the conductor sitting more firmly and securely in the through-opening. The close contact effectively protects the conductor from vibrations and movements, which improves measurement accuracy by maintaining the stable position of the conductor.

Secondly, the stable fixation of the conductor in the tapered through-opening reduces the need for regular calibrations. Since the conductor has less freedom to move, the measurement conditions remain constant, which increases the reliability of the data. This consistency is crucial for applications requiring high precision and minimizes the effort required for repeated calibrations that would otherwise be necessary to correct deviations caused by conductor movement.

Thirdly, the use of plastic as the housing material offers additional advantages. Plastic is not only elastic but also resistant to corrosion and lighter than many metals, which simplifies the handling and installation of the device. In addition, plastic provides electrical insulation, which improves safety when handling electrical components.

Finally, the use of a tapered edge in combination with an elastic housing material facilitates the assembly and maintenance of the device. The conductor can be easily inserted into and removed from the through-opening without risking that the housing material breaks or becomes permanently deformed. This makes the device more user-friendly and durable overall.

In yet another embodiment, the specified device comprises an additional through-opening through the housing, through which a connection interface for the coreless sensor can be guided.

The addition of a further through-opening in the housing for guiding a connection interface for the coreless sensor brings significant advantages for the stability and reliability of the entire measuring device, which in turn contributes to reducing the need for calibration. The connection interface, understood as an electrical point at which the sensor's measurement signals can be tapped, plays a central role in the integration and protection of the electronic connections.

Firstly, a dedicated through-opening for the connection interface allows for an orderly and secure routing of the sensor's electrical connections. This is particularly important to avoid mechanical stresses on the cables and plug connectors that could otherwise arise from bending or pulling during operation or installation. Organized cable routing not only contributes to the longevity of the electronic components but also ensures that signal integrity is not impaired by physical influences.

Secondly, the separate through-opening ensures that the sensory and electrical components are physically separated. This separation is critical in order to minimize interference or electromagnetic disturbances between the current-carrying conductor and the sensitive measurement signals of the sensor. Stable and interference-free signal transmission is essential for the accuracy of the measurement data and can reduce the frequency of necessary calibrations, as the measurement conditions become more reliable and consistent.

Thirdly, the clear structuring and secure accommodation of all components improve the overall stability of the device. The defined placement of the connection interface in its own through-opening supports a systematic design approach that protects against mechanical faults during operation. This robust configuration promotes consistent sensor performance by ensuring a constant environment without disruptive influences.

Finally, providing a dedicated through-opening for the connection interface promotes simplified maintenance and easier accessibility of the electrical connections for inspection or repair. This simplifies the maintenance process and reduces the likelihood of errors or damage that could otherwise result from improper handling.

### BRIEF DESCRIPTION OF THE DRAWINGS

The above-described features, characteristics, and advantages of this invention, as well as the manner in which they are achieved, will become more understandable in connection with the following description of exemplary embodiments, which are explained in greater detail in relation to the drawing. The drawings show:

FIG. 1a a perspective view of a first device for positioning a coreless sensor,

FIG. 1b the device of FIG. 1a in an exploded view,

FIG. 1c the device of FIG. 1a in a first manufacturing state,

FIG. 1d the device of FIG. 1a in a second manufacturing state,

FIG. 2a a perspective view of a second device for positioning a coreless sensor,

FIG. 2b the device of FIG. 2a in a first manufacturing state,

FIG. 2c the device of FIG. 2a in a second manufacturing state,

FIG. 2d the device of FIG. 2a in a sectional view,

FIG. 3a a perspective view of a third device for positioning multiple coreless sensors, and

FIG. 3b the device of FIG. 3a in an exploded view.

In the figures, identical technical elements are provided with the same reference numerals and described only once. The figures are purely schematic and do not represent the actual geometric proportions.

### DETAILED DESCRIPTION

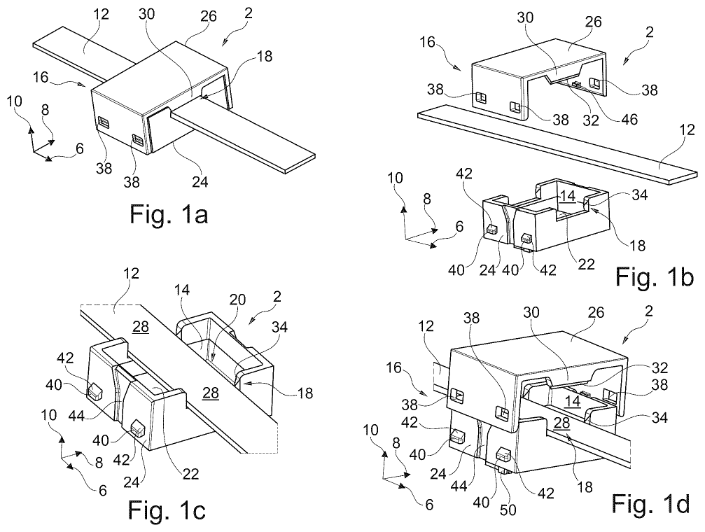

Reference is made to FIGS. 1a, 1b, 1c, and 1d, which respectively show a perspective view of a first device 2 for positioning a coreless sensor, the device 2 from FIG. 1a in an exploded view, the device 2 from FIG. 1a in a first manufacturing state, and the device 2 from FIG. 1a in a second manufacturing state.

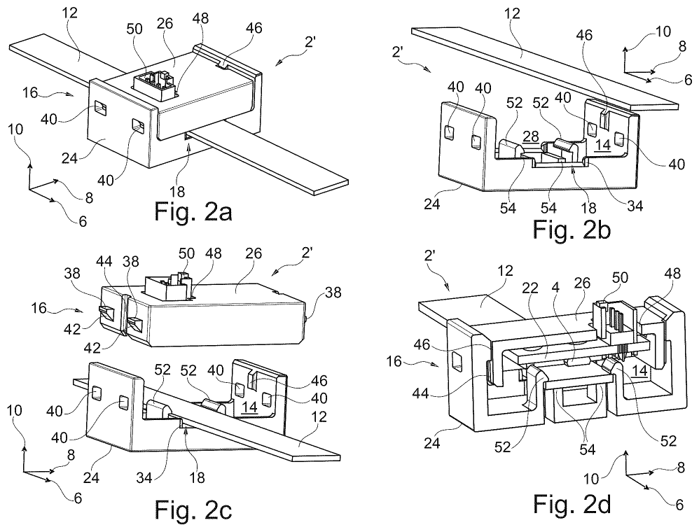

The coreless sensor 4 is not visible in the perspective views of FIGS. 1a to 1d, but is shown in FIG. 2d. The coreless sensor 4, also referred to as a coreless sensor, is a sensor that operates without a ferromagnetic core. Traditional sensors often use a ferromagnetic core to concentrate the magnetic field and increase sensitivity. The coreless sensor 4 does without such a core and instead uses other techniques to enable precise measurements. This offers various advantages, such as smaller size, lower weight, higher precision, and improved linearity.

The coreless sensor 4 is characterized by high precision and reliability and thus contributes to improved vehicle control and safety.

For clarity, the device 2 is described below in a spatial frame defined by a longitudinal direction 6, a transverse direction 8 transverse to the longitudinal direction 6, and a vertical direction 10 transverse to both the longitudinal direction 6 and the transverse direction 8.

The coreless sensor 4, which is not shown in FIGS. 1a to 1d, is arranged on a printed circuit board 12 and is designed to detect a current flowing through an electrical conductor, here in the form of a busbar. In the context of the coreless sensor 4, the busbar 12 is a component that serves as an electrical distribution and connection mechanism. The busbar 12 is typically a flat, conductive strip made of metal (often copper or aluminum) that connects multiple electrical circuits or components by providing a common current path.

In the automotive industry, the combination of the busbar 12 and coreless sensor 4 is used in various applications. One key application area is the battery management system (BMS) in electric vehicles. Here, the coreless sensor 4 monitors the current flow through the busbar 4 to precisely detect and control the battery's state of charge and health. This combination enables efficient and safe power distribution within a vehicle. Another area of application is the monitoring of electric motors. The coreless sensor 4 detects the current flow through the motor windings and thereby provides important information on motor performance and operational status. This is critical for optimizing motor control and avoiding overloads or malfunctions. In addition, the combination of busbar 12 and coreless sensor 4 is used in charging infrastructure for electric vehicles. It allows precise monitoring and control of the charging process, which leads to higher efficiency and safety during charging. This is especially important in fast-charging stations where high currents must be managed.

The position of the coreless sensor 4 relative to the busbar 12 must be precisely defined and fixed. This includes both the horizontal placement in the vertical direction 10 and the vertical placement in the transverse direction 8, in order to ensure optimal measurement conditions.

The coreless sensor 4 must be positioned centrally over the busbar 12 in the transverse direction 8 in order to evenly detect the entire magnetic field generated by the current flow. A central alignment ensures that the coreless sensor 4 detects the magnetic field evenly across the entire width of the busbar 12.

Furthermore, the vertical distance in the vertical direction 10 between the coreless sensor 4 and the surface of the busbar 12—which is not otherwise referenced—is of great importance. This distance must be precisely defined to ensure that the coreless sensor 4 is in the optimal position for magnetic field measurement. If the distance is too great, sensitivity and measurement accuracy are impaired, whereas too small a distance increases the risk of mechanical damage.

Exact positioning also includes aligning the coreless sensor 4 parallel to the busbar 12, to ensure that the coreless sensor 4 delivers consistent and reproducible measurements. Any tilt or deviation from parallel alignment results in distorted measurement values. Additionally, the coreless sensor 4 must be mounted in a way that ensures it is securely and stably fixed, to withstand vibrations and movements that can occur in a moving vehicle.

Only when the alignment of the coreless sensor 4 to the busbar 12 is precise will uniform detection of the magnetic field be ensured, electromagnetic interference and noise minimized, thermal stability maintained, and mechanical stability achieved. These factors are critical for the precision, reliability, and long-term stability of measurements in applications such as the battery management system, motor monitoring, and electric vehicle charging infrastructure.

The previously mentioned precise alignment of the coreless sensor 4 to the busbar 12 is conventionally ensured by a calibration process involving multiple steps aimed at determining the optimal position of the coreless sensor 4 relative to the busbar 12 and ensuring that it provides precise and reliable measurements.

The calibration process usually begins with the installation of the coreless sensor 4 in the intended position relative to the busbar 12—i.e., seen in the transverse direction 8, centered over the width of the busbar, and in the vertical direction 10, at an optimal vertical distance to the surface. Test currents are then passed through the busbar 12, during which the coreless sensor 4 detects the magnetic fields generated. The measured data are analyzed to ensure that the coreless sensor 4 provides consistent and accurate measurement values. During this calibration process, different positions in the transverse direction 8 and distances in the vertical direction 10 are tested. The coreless sensor 4 is moved incrementally, and measurements are repeated until the optimal position is found at which the readings are most accurate and consistent. This can be supported by mechanical adjustment devices, laser alignment tools, and other precise positioning techniques.

However, this calibration process is time-consuming and requires specialized equipment and expertise, which increases production costs. Additionally, calibration can be difficult and complex in a mass production setting, since each coreless sensor 4 must be individually adjusted and tested. Another drawback is the potential for drift and wear over time, which means the coreless sensor 4 must be recalibrated regularly to ensure its accuracy. These recurring maintenance requirements can increase operational costs and compromise the overall system reliability if not properly addressed.

This is where device 2 intervenes with the concept of mechanically defining the alignment of the coreless sensor 4 relative to the busbar 12. For this purpose, device 2 comprises a housing 16 delimiting an interior space 14 for receiving the coreless sensor 4. A through-opening 18 extends through this housing 16 in a current flow direction, which in the present embodiment corresponds to the longitudinal direction 6, whereby the busbar 12 is insertable in a form-fit manner transverse to the current flow direction 6, i.e., in the transverse direction 8 and vertical direction 10. The alignment of the coreless sensor 4 to the busbar 12 is determined by a holding device 20 arranged within the interior space 14, which positions the coreless sensor 4 at a predetermined distance in the transverse direction 8 and vertical direction 10 relative to the busbar 12.

The holding device 20 for the coreless sensor 4 implements the core idea of device 2, which is to securely and precisely position the coreless sensor 4 in the interior space 14 of the housing 16 relative to the busbar 12. This holding device 20 may use any mechanical connection types—material-fit, form-fit, or force-fit—to ensure the positioning of the coreless sensor 4 in the transverse direction 8, longitudinal direction 6, and vertical direction 10 within the housing 16. In the present embodiment, the holding device 20 supports a printed circuit board 22 carrying the coreless sensor 4 within the interior space of the housing 16 in a form-fit manner against walls (not further referenced) in the transverse direction 8 and longitudinal direction 6, and in a material-fit or force-fit manner in the vertical direction 10. The form-fit ensures stable positioning of the coreless sensor 4 without lateral movement. In the vertical direction 10, the printed circuit board 22 carrying the coreless sensor can be held by spring mechanisms, clamping devices, or adhesive connections in a force-fit or material-fit manner to ensure precise vertical positioning and resistance to vibrations or movement.

In this way, the holding device 20 for the coreless sensor 4 ensures precise alignment of the sensor to the busbar 12 already at the time of installation, which is maintained consistently even during operation in a vehicle. This brings several significant advantages over conventional calibration. First, the need for elaborate calibration procedures is significantly reduced or even eliminated, since the precise positioning of the coreless sensor 4 is already ensured by the holding device 20. This reduces production time and cost, as each coreless sensor 4 does not need to be individually calibrated.

Second, the mechanical fixation by the holding device 20 offers a stable long-term positioning that is independent of external influences such as vibrations, thermal expansion, or mechanical stress. This greatly enhances the long-term stability and reliability of the measurements, as the coreless sensor 4 does not need to be readjusted or recalibrated. Third, potential measurement errors caused by incorrect calibration are prevented from the outset through exact mechanical positioning. This results in higher measurement accuracy and consistency.

Finally, the mechanical fixation by the holding device 20 for the coreless sensor 4 also simplifies the design and maintenance. The coreless sensor 4 can be more easily replaced without requiring a complex recalibration, which further improves the maintainability and system reliability. Overall, the precise positioning provided by the holding device 20 for the coreless sensor 4 offers substantial advantages in terms of cost, reliability, accuracy, and maintainability compared to conventional calibration methods.

The housing 16 may be designed in various ways to optimally accommodate and protect the coreless sensor 4. It may be single-stage or multi-stage, depending on the specific requirements of the application. A single-stage design consists of a single housing part that forms the entire interior space 14 and directly accommodates the sensor as well as the busbar 12. This construction offers simple assembly and robust stability, as there are fewer joints that could potentially represent weak points. Another alternative is a modular housing 16, composed of multiple interconnected individual parts. This allows flexible adaptation to different installation situations and facilitates expansion or modification of device 2.

In the present embodiment, the housing 16 comprises a first housing part 24 and a second housing part 26, with which the first housing part 24 can be closed. This two-part construction enables easier installation and maintenance of the coreless sensor 4. The first housing part 24 serves as the base that forms the interior space 14 and the through-opening 18 for the busbar 12. The coreless sensor 4 is positioned on the printed circuit board 22 inside the interior space 14, whereby the first housing part 24 ensures form-fit retention of the printed circuit board 22 in the transverse direction 8 and longitudinal direction 6.

The second housing part 26 closes the first housing part 24 to fully cover the interior space 14. This not only provides additional protection against external influences such as dust, moisture, and mechanical shocks. By closing with the second housing part 26, it is also ensured that the coreless sensor 4 is form-fitted and thus stably held in the vertical direction 10.

For this purpose, the through-opening 18, transverse to the current flow direction 6, comprises recesses 28 that are open on one side and formed in the first housing part 24, which are closed when the second housing part 26 is placed on top. The recesses 28 are, for clarity, not all provided with individual reference numerals. On the first housing part 24, guide plates 30 are formed, with each guide plate 30 inserted into a recess 28, thereby pressing the busbar 12 into the recesses 28. Not all guide plates 30 are visible in the perspective of the figures. The pressing action is intensified by a vertical compression lip 32 formed on the underside of each guide plate 30 in the vertical direction 10, i.e., a tapering.

The vertical compression lip 32 ensures that the busbar 12 is fixed in the vertical direction 10 both form-fit and force-fit within the through-opening 18, compensating for tolerances introduced by assembling the two housing parts 24, 26 into the device 2. The tapering of the vertical compression lip 32 generates additional pressure on the busbar 12, thereby ensuring a secure mechanical connection. This added pressure guarantees that the coreless sensor 4 remains in its intended position even under vibrations and mechanical stresses during vehicle operation.

In addition to the vertical compression lips 32, transverse compression lips 34 may be formed in the recesses 28, which are similarly shaped but aligned in the transverse direction 8. Not all transverse compression lips 34 are individually referenced in the figures. The transverse compression lips 34 ensure that the busbar 12 is also fixed in the transverse direction 8, both form-fit and force-fit. The tapering of the transverse compression lips 34 generates additional pressure on the busbar 12.

The transverse compression lips 34 not only further stabilize the busbar 12 during operation, but also ensure that the busbar 12 is held securely and firmly during assembly, facilitating insertion and ensuring correct positioning. Once fixed, the transverse compression lips 34 provide a permanent fixation that does not yield even under vibrations and mechanical stress. Thus, the transverse compression lips 34 ensure not only stable and secure fixation of the busbar 12 in the transverse direction 8, but also simplified installation, as the busbar 12 is automatically guided into and fixed in the correct position, reducing the need for additional adjustments or tools.

Another advantage is improved resistance to vibration and shock, since the compression lips serve as additional fixing elements providing multidimensional stabilization. This is particularly important in the harsh operational environment of a vehicle, where constant vibrations and mechanical loads occur. Moreover, the transverse compression lips 34 can help reduce installation errors by ensuring correct alignment of the busbar 12 and facilitating the positioning of the coreless sensor 4.

The second housing part 26 is designed to be fitted over the first housing part 24. For this purpose, latching lugs 38 are formed on the first housing part 24, which can latch into specially provided latching recesses 40 of the second housing part 26. Not all of these latching lugs 38 and latching recesses are visible in the perspective of the figures. The latching occurs automatically when the second housing part 26 is placed over the first housing part 24, thereby ensuring a stable and secure connection between the two housing parts 24, 26.

To facilitate the latching of the latching lugs 38, they are provided with ramps 42. These ramps 42 are beveled surfaces on the latching lugs 38, which provide smooth and low-friction guidance into the latching recesses 40 when the second housing part 26 is placed on top. This design reduces the force required for assembling the housing parts and simplifies the overall installation.

The overfitting design of the second housing part 26 over the first housing part 24 offers several advantages. First, it enables quick and easy assembly, as the housing parts can be connected without additional tools or complex fastening methods. Second, the latching of the latching lugs 38 into the latching recesses 40 ensures a secure and permanent connection that remains stable even under vibrations and mechanical stress.

Additionally, this design offers increased flexibility and maintenance convenience. If maintenance or replacement of the coreless sensor 4 is required, the second housing part 26 can be easily removed by releasing the latching lugs 38 from the latching recesses 40. This facilitates access to the interior space 14 and the components contained therein.

Furthermore, guide grooves 44, running in the vertical direction 10, are formed on the first housing part 24. Corresponding guide protrusions 46, formed on the second housing part 26, can be inserted into each guide groove 44. Not all guide grooves 44 and guide protrusions 46 are visible in the perspective of the figures. For clarity, not all of them are individually referenced. The guide protrusions 46 are designed to engage with the corresponding guide grooves 44, enabling the two housing parts 24, 26 to be assembled in the vertical direction.

The term guide protrusion 46 refers to a projection whose length in the vertical direction 10 is not limited. The length of each guide protrusion 46 can be selected depending on the application and affects the stability and precision of the connection. A longer guide protrusion 46 offers a larger contact surface within its guide groove 44, which improves mechanical guidance and reduces the risk of misalignment during assembly. In addition, a longer guide protrusion 46 provides greater stability against lateral movements and mechanical loads, enhancing the overall integrity of the connection. On the other hand, a shorter guide protrusion 46 offers the advantage of minimizing the risk of tilting and reducing friction during assembly. This makes it easier to insert and join the housing parts 24, 26, enabling faster and simpler assembly.

The guidance formed by each guide groove 44 and guide protrusion 46 significantly facilitates the assembly of the housing parts 24, 26, as it enables clear and precise alignment. This minimizes assembly errors and ensures that the housing parts 24, 26 are correctly joined. Secondly, the mechanical guidance ensures a stable and robust connection that remains reliable even under vibrations and mechanical stresses during vehicle operation. Finally, the precise alignment of the housing parts 24, 26 contributes to the accuracy and reliability of the entire system by ensuring that the coreless sensor 4 remains in the optimal position relative to the busbar 12.

The guide grooves 44 may be tapered in shape at least in certain areas. This design of the guide grooves 44 facilitates the insertion of the corresponding guide protrusion 46 and ensures precise centering of the housing parts 24, 26 during the assembly step. Due to the tapered shape, each guide protrusion 46 is automatically guided into the correct position, which further simplifies the assembly process and reduces the risk of misalignment. Additionally, the tapered shape of each guide groove 44 can increase the stability of the connection by ensuring a form-fit and secure hold of the corresponding guide protrusion 46 within the groove.

In addition, the housing 16 comprises another through-opening 48, through which a connection interface 50 for the coreless sensor 4 can be guided. The through-opening 48 is not visible in the perspective of FIGS. 1a to 1d, but is shown in FIG. 2a. It allows access to the connection interface 50, which provides the connection of the coreless sensor 4 to external devices or systems. The through-opening 48 is positioned in such a way that the connection interface 50 can be easily and securely routed through the housing 16 during assembly. In doing so, the connection interface 50 also contributes to the positioning of the coreless sensor 4 by creating a form-fit transverse to the vertical direction 10. This increases the stability and accuracy of the sensor positioning without compromising the seal of the housing. The described construction simplifies the installation and connection of the sensor 4 and ensures reliable data transmission and power supply.

The assembly of the coreless sensor 4 takes place in several steps:

First, the printed circuit board 22 carrying the coreless sensor 4 is inserted into the first housing part 24. Care is taken to ensure that the printed circuit board 22 is seated in a form-fit and stable manner in the designated position within the interior space 14 of the first housing part 24. It must also be ensured that the connection interface 50 is guided through the additional through-opening 48 in the first housing part 24. This automatically ensures that the connection interface 50 is correctly positioned and accessible.

Next, the second housing part 26 is placed onto the first housing part 24. The guide protrusions 46 are inserted into the guide grooves 44. The two housing parts 24, 26 are brought together transverse to the current flow direction 6. Both housing parts are pushed together until the ramps 42 are reached. With slight pressure in the direction opposite to the vertical direction 10, the latching lugs 38 snap into the latching recesses 40, thereby ensuring a stable and secure connection of the two housing parts.

For disassembly, a tool such as a screwdriver is required to release the latching lugs 38. Since there is no ramp on the opposite side of the latching lugs, the screwdriver must be inserted between the housing parts 24, 26 to lever the latching lugs 38 out of the latching recesses 40. Once the latching lugs 38 are released, the second housing part 26 can be removed from the first housing part 24 by withdrawing the guide protrusions 46 from the guide grooves 44. Finally, the printed circuit board 22 with the coreless sensor 4 can be removed from the first housing part 24.

Reference is made to FIGS. 2a, 2b, 2c, and 2d, which respectively show a perspective view of a second device 2′ for positioning the coreless sensor 4, the device 2′ from FIG. 2a in a first manufacturing state, the device 2′ from FIG. 2a in an exploded view, and the device 2′ from FIG. 2a in a sectional view.

The main difference in the second device 2′ lies in the fact that the functions of the first housing part 24 and the second housing part 26 are reversed. In this embodiment, the first housing part 24 now solely holds the busbar 12. All other elements of the housing parts are arranged in reverse to maintain the functionality.

Specifically, this means that the through-opening 18, which was previously located in the first housing part 24, is now found in the second housing part 26. Accordingly, the guide groove 44, which in the first device 2 extends transverse to the current flow direction 6 in the first housing part 24, is now located on the second housing part 26. The corresponding guide protrusion 46, which in the first device 2 is formed on the second housing part 26, is now present on the first housing part 24. Furthermore, the latching lugs 38 and latching recesses 40 are also reversed: the latching lugs 38 with the ramps 42 are now on the second housing part 26, while the latching recesses 40 are found on the first housing part 24.

This reversed arrangement of the housing parts means that during assembly, the guide protrusion 46 of the first housing part 24 is inserted into the guide groove 44 of the second housing part 26. The second housing part 26 is then pushed onto the first housing part 24 until the ramps 42 guide the latching lugs 38 into the latching recesses 40. Pressure in the opposite direction of the vertical direction 10 causes the latching and ensures a stable connection of the two housing parts.

Through this reversed arrangement, the fundamental functionality of the first device 2 is retained in the second device 2′. However, in the first device 2, the first housing part 24 positions both the busbar 12 and the coreless sensor 4. This means the entire responsibility for the precise alignment and stability of the coreless sensor 4 rests solely with the first housing part 24. In contrast, in the second device 2′, the positioning of the busbar 12 and the coreless sensor 4 is decoupled. The first housing part 24 now solely assumes the holding function for the busbar 12, while the precise positioning of the coreless sensor 4 is handled by the second housing part 26. This decoupling of the positioning functions offers several advantages:

Firstly, the complexity of the individual housing parts is reduced. The first housing part 24 can focus on the stable and secure holding of the busbar 12 without also needing to ensure the precise alignment of the sensor. This simplifies the design and can lower manufacturing costs. Secondly, assembly flexibility is increased. Since the positioning of the coreless sensor 4 and the busbar 12 is now separate, both elements can be inserted into the housing and adjusted independently. This facilitates the assembly process and reduces the risk of errors, as the adjustment of the busbar 12 and the sensor 4 does not have to occur simultaneously. Thirdly, this decoupling increases the stability and accuracy of the entire device 2′. Since each housing half now fulfills a specific task, both parts can be designed to optimally perform their respective function. The busbar 12 is stably fixed in the first housing part 24, while the second housing part 26 precisely positions the coreless sensor 4. This results in an overall more robust and reliable design.

Additionally, the decoupling of the positioning tasks offers advantages for maintenance and repair. If replacement or adjustment of the busbar 12 or the sensor 4 is required, this can be carried out independently of one another, without having to dismantle the entire device. This saves time and effort and improves the maintainability of the device.

In the second device 2′, the first housing part 24 is equipped with additional latching hooks 52 and support legs 54, which allow precise and stable positioning of the busbar 12 in the vertical direction 10. The latching hooks 52 hold the busbar 12 in the vertical direction 10, while the support legs 54 serve as bearing points for the busbar 12 in the opposite direction. These design features contribute significantly to the stability and accuracy of the second device 2′.

The latching hooks 52 are integrated into the first housing part 24 and are located—viewed in the transverse direction 8—in front of and behind the support legs 54, to form-fit the busbar 12 in the vertical direction 10. When the busbar 12 is placed onto the support legs 54, which are also integrated into the first housing part 24, the latching hooks 52 grip around the busbar 12 so that it is held form-fit in and against the vertical direction.

In this way, the latching hooks 52 ensure secure and firm retention of the busbar 12. By snapping the busbar 12 into the latching hooks 52, it is reliably held in the desired position, thereby preventing undesired movement in the vertical direction 10. This form-fit retention by the latching hooks 52 complements the force-fit function of the transverse compression lips 34, especially during installation. Additionally, the support legs 54 provide further stability by serving as resting points for the busbar 12. The busbar 12 is positioned in the vertical direction 10 between the latching hooks 52 and the support legs 54, ensuring exact alignment and stable positioning. The support legs 54 carry the weight of the busbar 12 and prevent sagging or slipping, distributing the mechanical load evenly. This additional securing of the busbar 12 improves the structural integrity and functional reliability of the entire device 2′. The combination of latching hooks 52 and support legs 54 ultimately ensures that the busbar 12 is not only precisely positioned, but also held stably under operating conditions. This is especially important to ensure the reliable function of the coreless sensor 4, since a stable busbar 12 increases the accuracy of measurements and the long-term reliability of the device.

To assemble the second device 2′, the printed circuit board 22 carrying the coreless sensor 4 is first inserted—analogous to the first device 2—but into the second housing part 26. Unlike the first device 2, the busbar 12 is then inserted into the other housing part 24. To do this, the busbar 12 is pushed through the latching hooks 52 until it rests firmly on the support legs 54. The latching hooks 52 then grip the busbar 12 and hold it securely in the vertical direction 10. The remaining assembly is carried out analogous to the first device 2.

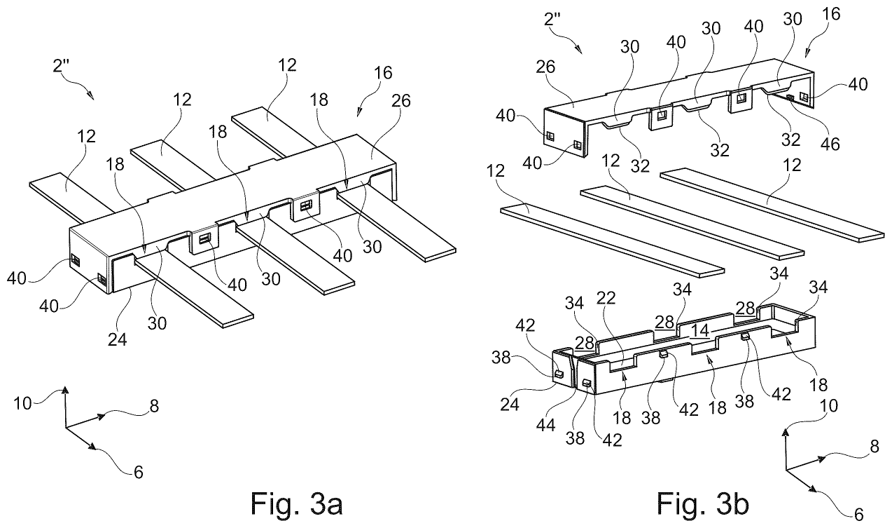

Finally, reference is made to FIGS. 3a and 3b, which respectively show a perspective view and an exploded view of a third device 2″ for positioning multiple coreless sensors.

The third device 2″ is essentially constructed like the first device 2, but in this case multiple busbars 12 are positioned parallel to each other. To ensure secure retention, the latching elements 38, 40, 42 are also arranged between the individual busbars 12.

The third device 2″ can likewise be realized analogously based on the design of the second device 2′.

### REFERENCE NUMERAL LIST

2, 2′, 2″ Device for positioning a coreless sensor
4 Coreless sensor
6 Current flow direction
8 Transverse direction (perpendicular to current flow direction)
10 Vertical direction (perpendicular to current and transverse directions)
12 Electrical conductor/Busbar
14 Interior space of the housing
16 Housing
18 Through-opening for the electrical conductor
20 Holding device for the coreless sensor
22 Printed circuit board (with sensor)
24 First housing part
26 Second housing part
28 Recess (one-sided open opening in the housing)
30 Guide plate
32 Vertical compression lip
34 Transverse compression lip/Transverse securing element
38 Latching lug
40 Latching recess
42 Ramp (on latching lug)
44 Guide groove
46 Guide protrusion
48 Additional through-opening for connection interface
50 Connection interface for the coreless sensor
52 Latching hook for securing the busbar
54 Support leg for supporting the busbar

1. A device for positioning a coreless sensor relative to an electrical conductor carrying an electric current in a current flow direction, comprising:
a housing delimiting an interior space for receiving the coreless sensor;
a through-opening passing through the housing in the current flow direction, into which the electrical conductor is insertable in a form-fit manner transverse to the current flow direction; and
a holding device arranged in the interior space at a predetermined distance transverse to the current flow direction for holding the coreless sensor in a predetermined position relative to the through-opening.

2. The device according to claim 1, further comprising latching hooks configured to hold the electrical conductor in a direction transverse to the current flow direction.

3. The device according to claim 2, further comprising support legs for supporting the electrical conductor, such that the electrical conductor, viewed in the direction transverse to the current flow direction, is positioned between the latching hooks and the support legs.

4. The device according to claim 1, wherein the housing comprises a first housing part and a second housing part, wherein the first housing part can be closed.

5. The device according to claim 4, wherein the through-opening is formed as a one-sided open recess, transverse to the current flow direction, in at least one of the housing parts, which can be closed by placing the respective other housing part.

6. The device according to claim 5, wherein transverse securing elements are formed on the recess.

7. The device according to claim 4, further comprising latching elements configured to latch the two housing parts together in an assembled state of the housing.

8. The device according to claim 7, wherein the latching elements are arranged such that they permit tool-free assembly and require a tool for disassembly.

9. The device according to claim 4, further comprising a guide groove extending transverse to the current flow direction on one of the housing parts, into which a correspondingly formed guide protrusion on the other housing part is insertable for guided assembly of the two housing parts into the housing.

10. The device according to claim 1, wherein the guide groove is at least partially tapered in cross-section to facilitate centering of the guide protrusion during assembly of the housing parts.

11. The device according to claim 1, wherein an edge of the through-opening is formed tapered in a direction transverse to the current flow direction.

12. The device according to claim 1, further comprising an additional through-opening through the housing, through which a connection interface for the coreless sensor is guidable.

13. The device according to claim 12, wherein the connection interface contributes to the positioning of the coreless sensor by creating a form-fit in the direction transverse to the vertical direction.

14. The device according to claim 1, wherein the holding device comprises a printed circuit board carrying the coreless sensor, the printed circuit board being fixed in the interior space of the housing in a form-fit manner in the transverse direction and longitudinal direction and in a force-fit or material-fit manner in the vertical direction.

15. The device according to claim 14, wherein the printed circuit board is retained in the vertical direction by one selected from a group consisting of spring mechanisms, clamping devices, and adhesive connections.
